(19) United States
(12) Patent Application Publication
(10) Pub. No.: US 2002/0047726 A1
(43) Pub. Date: Apr. 25, 2002

(54) Footless domino gate

(76) Inventors: Siva G. Narendra, Beaverton, OR (US); Yibin Ye, Hillsboro, OR (US); Vivek K. De, Beaverton, OR (US)

Correspondence Address: Alan K. Aldous, BLAKELY, SOKOLOFF, TAYLOR & ZAFMAN, LLP, 12400 Wilshire Boulevard, 7th Floor, Los Angeles, CA, 90025, US

(21) Appl. No.: 09/540,230

(22) Filed: Mar. 31, 2000

(51) Int. Cl. H03K 19/096

(52) U.S. Cl. 326/98

(57) ABSTRACT

In some embodiments, the invention includes a domino gate including a domino stage node and an evaluate network. The evaluate network includes a first group of transistors coupled between the domino stage node and a voltage reference node. The gate also includes a second group of transistors coupled between respective ones of inputs of the first group of transistors and the voltage reference node. The gate may be a precharge domino gate or a predischarge domino gate. The gate may comprise a pull-up transistor coupled to the domino stage node, the pull-up transistor including an input to receive a clock signal (Clk) and wherein the second group of transistors have inputs to receive a clock signal (Clk*), which is an inverse of Clk. Clk may lead or trial Clk*.

### BACKGROUND OF THE INVENTION

1. Technical Field of the Invention

The present invention relates to circuits and, more particularly, to domino circuits.

2. Background Art

Domino gates are often used in high performance complementary metal oxide semiconductor (CMOS) based circuits due to their speed advantage. Domino gates work on a principle of precharge followed by conditional evaluation. Reasons why domino gates are faster than static CMOS gates include absence of contention between the pull-up and pull-down networks when the input switches, making all the drive current available for either charging or discharging the output load capacitor. Also, the input load offered by the domino gate is often half that of a static CMOS gate since it has either only the p-channel metal oxide semiconductor PMOS or only the n-channel metal oxide semiconductor (NMOS) network.

Referring to FIG. 1, a conventional prior art domino OR gate 10 includes multiple inputs signals A1 . . . An to an evaluate network including n-channel field effect transistors (NFET devices) M1-1 . . . M1-n, where n may 2 or more. NFET devices M1-1 . . . M1-n are positioned between a domino stage node (DSN) and an NFET foot device M0. M0 is positioned between M1-1 . .. M1-n and a ground node having a voltage Vgnd. Gate 10 also includes a precharge p-channel field effect transistor (PFET device) M2, a keeper PFET device M3, and an output stage 14. In FIG. 1, output stage 14 is a static inverter, but could be a more elaborate output stage. During a precharge phase, a clock signal (clk) goes low. When Clk goes low, PFET device M2 is turned ON and a domino stage signal Q is pulled high to Vdd. As signal Q goes high, an inverter 18 turns on PFET device M3 which keeps signal Q high after Clk transitions high so that M2 is off. During an evaluation phase, clk is low so that M0 is on. If one or more of input signals A1 . . . An goes high, the corresponding NFET device(s) M1-1 . . . M1-n is turned ON pulling signal Q low (Vgnd). Note that M3 is overcome relatively easily. When signal Q goes low, an evaluated output signal Out goes high on conductor 16 at the output of output stage 14.

Foot device M0 is ordinarily included in an initial domino gate, although other domino gates could include a foot device. Foot device M0 is used as follows. Assume for whatever reason, it cannot be guaranteed that inputs A1 . . . An will stay low during the precharge phase. Because Clk is low during the precharge phase, foot device M0 is off during precharge. Therefore, if one of inputs A1 . . . An is high during the precharge phase, signal Q remains pulled up, because there is no path between node N1 and ground. By contrast, assume foot device M0 were not used and M1-1 . . . M1-n are between DSN and Vgnd. Also, assume one of inputs A1 . . . An were high for some portion of the precharge phase but is low at the end of the precharge phase. In that case, during the precharge phase, signal Q could be pulled low to Vgnd through the corresponding one of NFETs M1-1 . . . M1-n. However, even though all of inputs A1 . . . An were high by the end of the precharge phase, there would be no way to pull signal Q back high. (Keeper M3 would be off and clk may not be low long enough for M2 to pull signal Q high.) Therefore, if inputs A1 . . . An remained high during the evaluate phase, signal Q should be high, but instead would be low at the end of the evaluate phase.

In predischarge domino gates, the evaluate network is between the node of the domino stage output and the power supply signal (Vdd). During the predischarge phase, signal Q is pulled high and conditioning pulled low during an evaluate phase. Predischarge domino gates may include head devices between the evaluate network and Vdd for the case in which it cannot be guaranteed that the inputs will be a certain voltage during the predischarge phase.

Although the evaluate network is shown as parallel NFET devices it may also be parallel PFET devices and serial NFET and PFET devices or some combination of them.

It is known that it takes longer for a node to be pulled low through stacked transistors than through a single transistor. For that reason, foot devices and head devices cause delay in the speed of the domino gate.

Accordingly, there is a need for an improved domino gate.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 is a schematic representation of a prior art domino gate including a foot device.

FIG. 2 is a schematic representation of a domino gate according to some embodiments of the present invention.

FIG. 3 is a schematic representation of FETs of FIG. 2 and a portion of a driving circuit according to some embodiments of the invention.

FIG. 4 is a timing diagram illustrating the relationship between signals Clk and Clk* for some embodiments of FIG. 2.

FIG. 5 is a schematic representation of an inverter used to create signal Clk* from signal Clk.

FIG. 6 is a timing diagram illustrating the relationship between signals Clk and Clk* for some embodiments of FIG. 2.

FIG. 7 is a schematic representation of an inverter used to create signal Clk from signal Clk*.

FIG. 8 is a schematic representation of a domino gate according to some embodiments of the invention.

FIG. 9 is a schematic representation of a domino gate according to some embodiments of the invention.

FIG. 10 is a schematic representation of a die including domino gates according to some embodiments of the invention.

### DETAILED DESCRIPTION

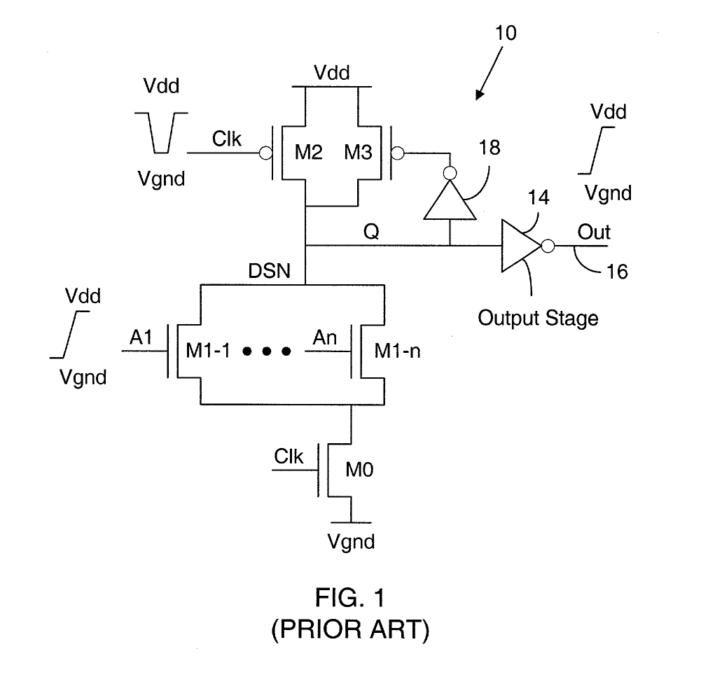

The invention involves a domino gate that includes an evaluate network including a first group of transistors coupled between the domino stage node and a voltage reference node. In a precharge domino gate, the voltage reference node may be a power supply node (called Vdd or Vcc). In a predischarge domino gate, the voltage reference node may be a ground voltage node (Vgnd or Vss). Rather than include a foot transistor (as in prior art FIG. 1), embodiments of the invention include a second group of transistors coupled between respective ones of gates of the evaluate network transistors and the voltage reference node.

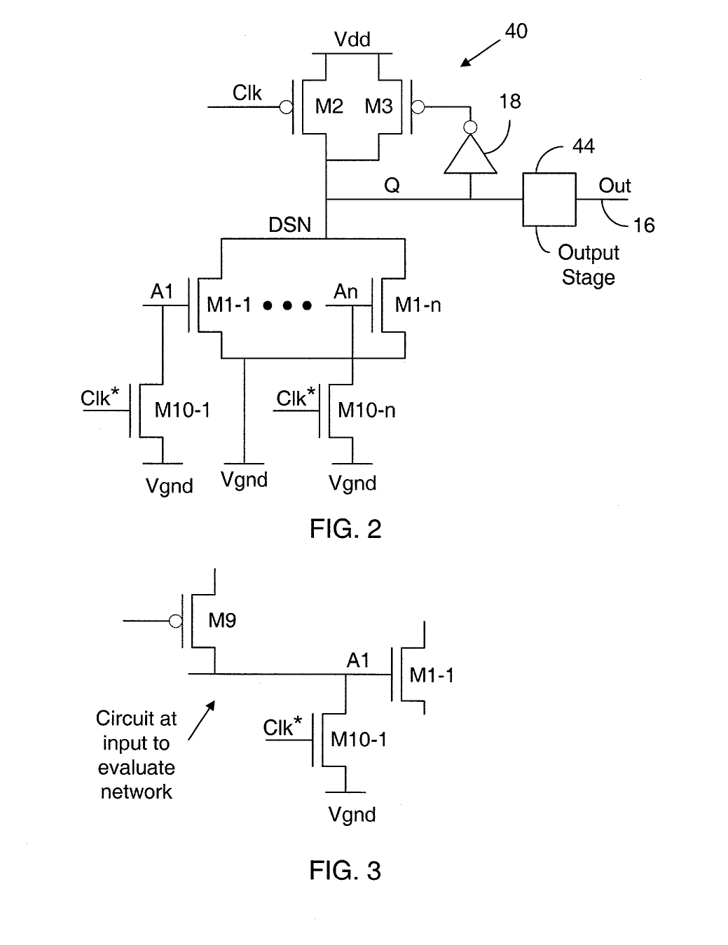

For example, referring to FIG. 2, a domino gate 40 includes an evaluate network including NFETs M1-1 . . . M1-n coupled between a domino stage node (DSN) and a ground reference node (Vgnd). An output stage 44 is coupled to the domino stage node. Output stage 44 may be an inverter or more complicated output stage, such as a dual function generator. An output signal Out is provided to conductor 16. NFETs M10-1 . . . M10-n are coupled between the gates of respective ones of M1-1 . . . M1-n and Vgnd.

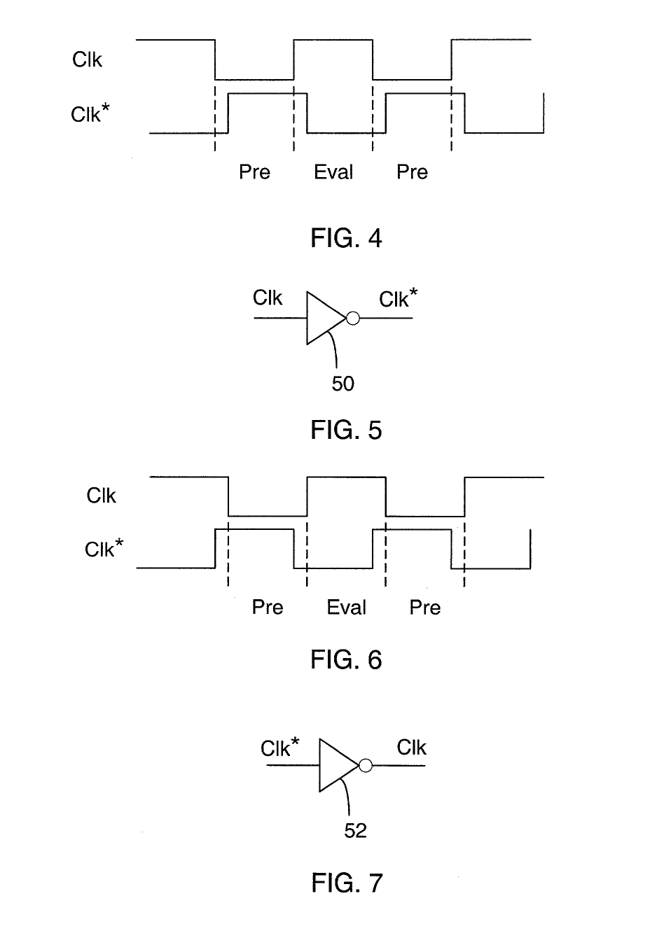

In a precharge phase, a clock signal Clk is low, and pull-up PFET M2 pulls a domino stage signal Q high on the domino stage node. Inverter 18 and keeper PFET M3 act to keep Q high as long at Q remains above a particular level. A clock signal Clk* is the inverse of Clk, although it may be a time shifted inverse of Clk. For example, FIG. 4 shows CLK* transitioning high slightly after Clk transitions low. (Note that in FIGS. 4 and 6, the delay between transitions of Clk and Clk* are not necessarily to scale with respect to the period of Clk and Clk*.) FIG. 6 shows Clk* transitioning high slightly before Clk transitions low. In FIGS. 4 and 6, “pre” refers to precharge phase and “eval” refers to evaluate phase.

There are various ways in which Clk and Clk* can be generated. For example, FIG. 5 shows Clk* being generated as an output of an inverter 50 to which Clk is received as an input. FIG. 6 shows Clk being generated as an output of an inverter 52 to which Clk* is received as an input. Alternatively, Clk and Clk* could be generated simultaneous rather than one from the other.

When Clk* is high (roughly during the precharge phase), M10-1 . . . M10-n are turned on pulling A1 . . . An low, thus guaranteeing that evaluate network transistors MI-1 . . . M1-n are off so that Q is not pulled low. When clk* is low (roughly during the evaluate phase), M10-1 . . . M10-n turn off thus allowing inputs A1 . . . An to control the state of evaluate network transistors M1-1 . . . M1-n.

FIG. 3 illustrates a portion of an driver circuit which includes a PFET pull-up transistor M9. Transistors M10-1 . . . M10-n should be sized and otherwise selected to be strong enough to overcome driver circuit pull-up or keeper transistors to pull M1-1 . . . M1-n close to ground, but not so strong as to significantly slow down the transition of the input signals to M1-1 . . . M1-n.

For the circuit of FIG. 2, the arrangement of FIG. 4 may have lower current, but may have a slower evaluation than the arrangement of FIG. 6, because in FIG. 4 M1-1 . . . M1-n are off for a brief moment in the evaluation phase. The arrangement of FIG. 6 may be faster, but could have a higher current during the evaluation phase, than the arrangement of FIG. 4, because in FIG. 6, M1-1 . . . M1-n might be on for the very end of the precharge phase. For many, if not all circumstances, it would be desirable to have Clk and Clk* be as close to 180 degrees out of phase as is possible or practical.

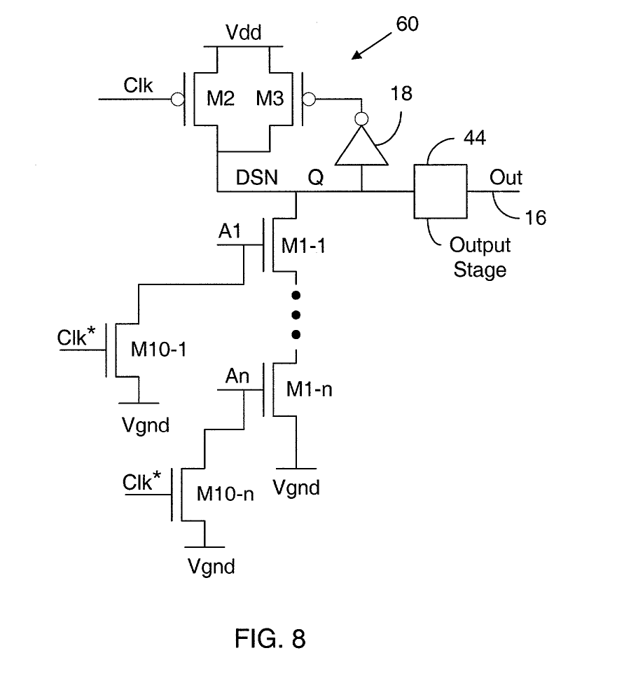

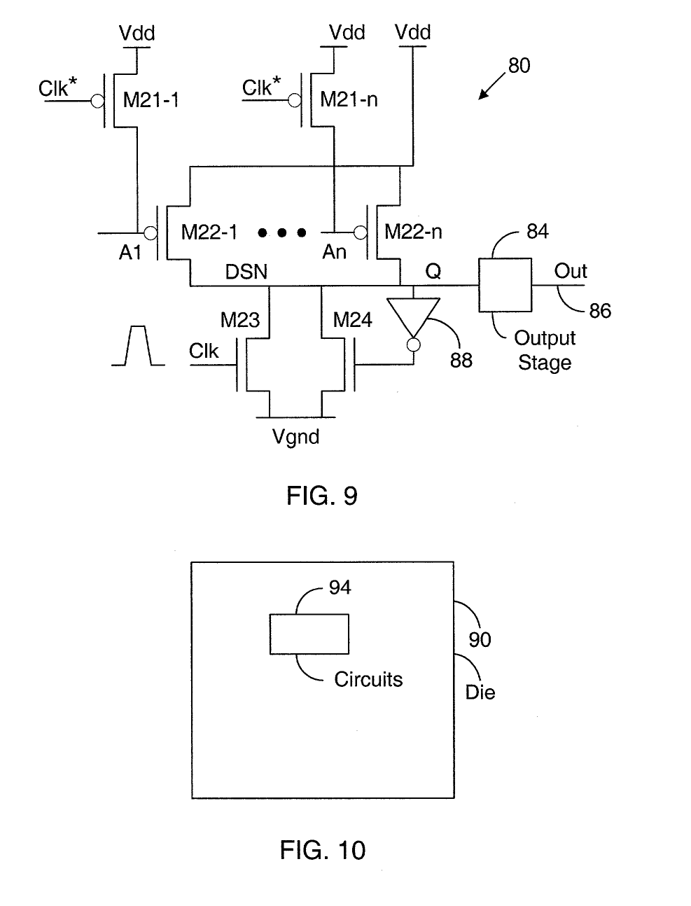

FIG. 8 illustrates a precharge domino gate 60 in which the evaluate network transistors are in series rather than in parallel. There could be a combination of series and parallel transistors. Indeed, the evaluate network is not restricted to a particular logical arrangement. FIG. 9 illustrates a predischarge domino gate 80 that includes a domino stage node, an output stage 84 (which may be the same as or different than output stage 44), an output conductor 86, and an evaluate network of PFETs M22-1 . . . M22-n. During a predischarge phase, CLK is high so that the domino stage node is pulled low through NFET M23. During the predischarge phase, the domino stage node is kept low through an inverter 88 and NFET M24 in an analogous way as described above. A clock signal CLK* is an inverse of CLK as described above in connection with FIGS. 2 and 4-7. When CLK* is low, PFETs M21-1 . . . M21-n are on pulling up inputs A1 . . . An and preventing them from turning on evaluate network transistors M22-1 . . . M22-n. When CLK* is high (roughly during evaluate phase), inputs A1 . . . An are released. Transistors M21-1 . . . M21-n may replace a series head transistor as in the prior art, but avoid stacked transistors which can significantly slow the switching speed of the domino gate.

FIG. 10 illustrates a die 80 in which circuits 94 are created. Circuits 94 may include a variety of domino circuits including gates such as those in one or more of FIGS. 2, 8, and 9. The gates of FIGS. 2, 8, and 9 may be D1K domino gates or at another stage of the domino circuit.

Other Information and Embodiments

Although embodiments of the invention are illustrated with FETs, other types of transistors could be used. If FETs are used, they may be MOSFETs or otherwise. Although the illustrated embodiments include enhancement mode transistors, depletion mode transistors could be used with modifications to the circuit which would be apparent to those skilled in the art having the benefit of this disclosure. The FETs may be zero biased, forward biased, or reverse biased. A FET gate is an example of an input, and more specifically a control input, to the FET.

The reference voltage (Vgnd or Vss) may be the same for M10-1 . . . M10-n as for other transistors or could be different. For example, in FIG. 2, the Vgnd node coupled to M10-1 . . . M10-n could be the same as or different than the Vgnd node coupled to M1-1 . . . M1-n. In FIG. 9, the Vdd node coupled to M21-1 . . . M21-n could be the same as or different than the Vdd node coupled to M22-1 . . . M22-n.

In the various illustrated circuits, NFETs could replace PFETs and vice versa, although it may lead to a low swing. For example, an NFET pull-up will pull up to only Vdd - Vt.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the invention. The various appearances “an embodiment,” “one embodiment,” or “some embodiments” are not necessarily all referring to the same embodiments.

When the disclosure refers to something as causing or resulting in something, that does not mean it is the sole cause of it.

If the specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Those skilled in the art having the benefit of this disclosure will appreciate that many other variations from the foregoing description and drawings may be made within the scope of the present invention. Accordingly, it is the following claims including any amendments thereto that define the scope of the invention.

What is claimed is:

1. A domino gate, comprising:
a domino stage node;
an evaluate network including a first group of transistors coupled between the domino stage node and a voltage reference node; and
a second group of transistors coupled between respective ones of inputs of the first group of transistors and the voltage reference node.

2. The gate of claim 1, wherein the voltage reference node is a power supply voltage node.

3. The gate of claim 1, wherein the voltage reference node is a ground voltage node.

4. The gate of claim 1, wherein the gate is a precharge domino gate.

5. The gate of claim 1, wherein the gate is a predischarge domino gate.

6. The gate of claim 1, wherein the domino gate is a D1K domino gate.

7. The gate of claim 1, wherein there is a one-to-one correspondence between the first group of transistors and the second group of transistors.

8. The gate of claim 1, wherein the first group of transistors are connected in parallel between the domino stage node and the voltage reference node.

9. The gate of claim 1, wherein the first group of transistors are connected in series between the domino stage node and the voltage reference node.

10. The gate of claim 1, wherein the gate is a precharge domino gate and the gate further comprises a pull-up transistor coupled to the domino stage node, the pull-up transistor including an input to receive a clock signal (Clk) and wherein the second group of transistors have inputs to receive a clock signal (Clk*), which is an inverse of Clk.

11. The gate of claim 1, wherein the gate is a predischarge domino gate and the gate further comprises a pull-down transistor coupled to the domino stage node, the pull-down transistor including an input to receive a clock signal (Clk) and wherein the second group of transistors have inputs to receive a clock signal (Clk*), which is an inverse of Clk.

12. A circuit, comprising:
a domino gate including:
a conductor to carry a clock signal (Clk);
a domino stage node;
a first transistor coupled to the domino stage node and having an input to receive the signal Clk;
an evaluate network including a first group of transistors coupled between the domino stage node and a voltage reference node;
a second group of transistors coupled to respective ones of inputs of the first group of transistors, the second group of transistors having inputs to receive a clock signal (Clk*), which is an inverse of Clk.

13. The circuit of claim 12, wherein Clk* is a time shifted inverse of Clk.

14. The circuit of claim 12, wherein Clk is inverted to created Clk*.

15. The circuit of claim 12, wherein Clk* is inverted to created Clk.

16. The circuit of claim 12, wherein the domino gate is a precharge domino gate and the first transistor is a pull-up device.

17. The circuit of claim 12, wherein the domino gate is a predischarge domino gate and the first transistor is a pull-down device.

18. The circuit of claim 12, further including a driving circuit to provide input signals to the first group of transistors, and wherein the second group of transistors are selected to have a strength that does not significantly slow the output circuit.

19. The circuit of claim 12, wherein the domino gate is an initial gate in a domino circuit.

20. The circuit of claim 12, wherein the domino gate includes an output stage connected to the domino stage node.

21. The circuit of claim 12, wherein the first transistor and the first and second groups of transistors are field effect transistors.

22. A domino gate, comprising:
a domino stage node;
an output stage coupled to the domino stage node;
an evaluate network including a first group of transistors coupled between the domino stage node and a first voltage reference node; and
a second group of transistors connected between respective ones of inputs of the first group of transistors and the second voltage reference node.

23. The gate of claim 22, wherein the second voltage reference is the first voltage reference node.

24. The gate of claim 22, wherein the first and second voltage reference nodes are a power supply voltage node.

25. The gate of claim 22, wherein the first and second voltage reference nodes are a ground voltage node.

26. The gate of claim 22, wherein the gate is a precharge domino gate.

27. The gate of claim 22, wherein the gate is a predischarge domino gate.

28. The gate of claim 22, wherein the gate is a precharge gate and the gate further comprises a pull-up transistor coupled to the domino stage node, the pull-up transistor including an input to receive a clock signal (Clk) and wherein the second group of transistors have inputs to receive a clock signal (Clk*), which is an inverse of Clk.

29. The gate of claim 22, wherein the gate is a predischarge gate and the gate further comprises a pull-down transistor coupled to the domino stage node, the pull-down transistor including an input to receive a clock signal (Clk) and wherein the second group of transistors have inputs to receive a clock signal (Clk*), which is an inverse of Clk.
